(19) United States
(12) Patent Application Publication
(10) Pub. No.: US 2026/0175592 A1
(43) Pub. Date: Jun. 25, 2026

(54) Electronic Device, Inkjet Printing Apparatus, And Method For Manufacturing Display Panel Using The Inkjet Printing Apparatus

(71) Applicant: Samsung Display Co., Ltd., Yongin-si (KR)

(72) Inventor: Futoshi Yoshida, Yokohama-shi (JP)

(73) Assignee: Samsung Display Co., Ltd., Yongin-si (KR)

(21) Appl. No.: 19/422,727

(22) Filed: Dec. 17, 2025

(30) Foreign Application Priority Data
Dec. 20, 2024 (JP) 2024-225261

(51) Int. Cl. B41J 3/28; B41J 3/54; B41J 11/00; B41J 11/06; B41J 29/02; G01N 21/64; H10K 59/12; H10K 71/13

(52) U.S. Cl. CPC B41J 3/28; B41J 3/543; B41J 11/00244; B41J 11/0095; B41J 11/06; B41J 29/02; G01N 21/6456; H10K 59/1201; H10K 71/135

(57) ABSTRACT

An inkjet printing apparatus according to an aspect of the present disclosure may include a first stage, a second stage which is disposed on the first stage and includes a heater, and on which a substrate including a print area is disposed, the print area overlapping the heater when viewed on a plane, a head unit disposed above the substrate, and including a plurality of printheads and an ink supply unit provided to supply, to the printheads, an ink including a material which emits excitation light in response to an electromagnetic wave, and a camera unit which is disposed on a side surface of the head unit and irradiates the ink with the electromagnetic wave and measures the excitation light generated in the ink.

### CROSS-REFERENCE TO RELATED APPLICATIONS

This application claims priority under 35 U.S.C. § 119 to Japanese Patent Application No. JP 2024-225261, filed on Dec. 20, 2024, the entire contents of which are incorporated herein by reference.

### BACKGROUND

The present disclosure herein relates to an electronic device, an inkjet printing apparatus, and a method for manufacturing a display panel by using the inkjet printing apparatus.

Organic light emitting diode display (OLED) devices, which generally have excellent luminance characteristics and viewing angle characteristics and do not require separate light source units unlike liquid crystal display devices, are attracting attention as next-generation flat panel display devices. The OLED devices do not require separate light sources and thus may be manufactured to have small weights and thin profiles. In addition, the OLED devices have characteristics such as low power consumption, high luminance, and high response speed.

An OLED display device includes a plurality of light emitting elements each including an anode, an organic emission layer, and a cathode. A hole and an electron are injected into the organic emission layer from the anode and the cathode, respectively, to form an exciton. As the exciton is transited into a ground state, the light emitting elements emit light.

When the light emitting elements are manufactured, the organic emission layer is manufactured using an inkjet printing apparatus. An organic material (or ink) for forming the organic emission layer may be ejected onto a substrate from the inkjet printing apparatus to form the organic emission layer.

The manufacture of the OLED device requires a high-resolution, precise patterning process. As a pixel size of the OLED device having high resolution decreases, the inkjet printing apparatus has to eject a smaller amount of ink. When the amount of the ink ejected from the inkjet printing apparatus is not finely controlled, a defective organic emission layer is manufactured. The development of inkjet printing apparatuses capable of finely controlling amounts of ink is required.

### SUMMARY

The present disclosure provides an inkjet printing apparatus capable of reducing a defect rate of an organic emission layer.

An aspect of the present disclosure provides an inkjet printing apparatus including a first stage, a second stage which is disposed on the first stage and includes a heater, and on which a substrate including a print area is disposed, the print area overlapping the heater when viewed on a plane, e.g. in plan view, a head unit disposed above the substrate and including a plurality of printheads and an ink supply unit provided to supply, to the printheads, an ink including a material which emits excitation light in response to an electromagnetic wave, and a camera unit which is disposed on a side surface of the head unit and irradiates the ink with the electromagnetic wave and measures the excitation light generated in the ink.

In an aspect, the head unit may further include a plurality of nozzles, and each of the nozzles may be disposed on a bottom surface of each of the printheads.

In an aspect, the nozzles may include a plurality of first nozzles defined as a first nozzle group and arranged in a first direction, a plurality of second nozzles defined as a second nozzle group and arranged in the first direction, and a plurality of third nozzles defined as a third nozzle group and arranged in the first direction. The first nozzle group, the second nozzle group, and the third nozzle group may be arranged in a second direction crossing the first direction.

In an aspect, the first nozzles and the third nozzles may be arranged in the same corresponding columns in the second direction, and the second nozzles may be disposed in columns, each of which is between the columns in which the first nozzles are disposed.

In an aspect, the ink may be provided to the print area of the substrate through the nozzles so that a first ink pattern is defined.

In an aspect, the first ink pattern may have a ring shape when viewed on a plane.

In an aspect, the ink may be provided to an area, spaced apart from the print area of the substrate, through the nozzles so that a second ink pattern is defined.

In an aspect, an adsorption hole may be defined in the second stage.

In an aspect, the camera unit may further include an electromagnetic irradiation unit.

In an aspect, each of the printheads may further include a pressure element.

In an aspect, the inkjet printing apparatus may further include a frame which connects the first stage to the head unit.

In an aspect of the present disclosure, a method for manufacturing a display panel includes preparing a first stage, arranging a second stage disposed on the first stage and including a heater, arranging, on the second stage, a substrate including a print area overlapping the heater when viewed on a plane, arranging, above the substrate, a head unit including a plurality of printheads, an ink supply unit provided to supply, to the printheads, an ink including a material which emits excitation light in response to an electromagnetic wave, and a plurality of nozzles disposed respective bottom surfaces of the printheads, arranging, on a side surface of the head unit, a camera unit provided to irradiate the ink with the electromagnetic wave and measure the excitation light generated in the ink, providing the ink to the print area of the substrate through the nozzles to form a first ink pattern, measuring the excitation light of the first ink pattern by the camera unit, allowing the nozzles to discharge the ink to an area spaced apart from the print area of the substrate to form a second ink pattern, and curing the second ink pattern to form an emission layer, and the display panel is manufactured by the curing of the second ink pattern to form the emission layer.

In an aspect, the camera unit may further include an electromagnetic irradiation unit, and the measuring of the excitation light of the first ink pattern by the camera unit may include irradiating the first ink pattern with the electromagnetic wave by the electromagnetic irradiation unit to measure a central position and a quantity of the excitation light.

In an aspect, the method for manufacturing the display panel may further include adjusting a time at which the ink supply unit discharges the ink, after the measuring of the excitation light of the first ink pattern by the camera unit.

In an aspect, each of the printheads may further include a pressure element, and the method for manufacturing the display panel may further include adjusting a discharge amount of the ink discharged from the nozzles by the pressure element, after the measuring of the excitation light of the first ink pattern by the camera unit.

In an aspect, the method for manufacturing the display panel may further include drying the first ink pattern by the heater, after the measuring of the excitation light of the first ink pattern by the camera unit.

In an aspect of the present disclosure, an electronic device includes a display device which displays an image, and a processor which processes an image signal and provides the image signal the display device. The display device may include a display panel prepared by preparing a first stage, arranging a second stage disposed on the first stage and including a heater, arranging, on the second stage, a substrate including a print area overlapping the heater when viewed on a plane, arranging, above the substrate, a head unit including a plurality of printheads, an ink supply unit provided to supply, to the printheads, an ink including a material which emits excitation light in response to an electromagnetic wave, and a plurality of nozzles respectively disposed bottom surfaces of the printheads, arranging, on a side surface of the head unit, a camera unit provided to irradiate the ink with the electromagnetic wave and measure the excitation light generated in the ink, providing the ink to the print area of the substrate through the nozzles to form a first ink pattern, measuring the excitation light of the first ink pattern by the camera unit, allowing the nozzles to discharge the ink to an area spaced apart from the print area of the substrate to form a second ink pattern, and curing the second ink pattern to form an emission layer, and the display panel is manufactured by the curing of the second ink pattern to form the emission layer.

### BRIEF DESCRIPTION OF THE FIGURES

The accompanying drawings are included to provide a further understanding of the present disclosure, and are incorporated in and constitute a part of this specification. The drawings illustrate aspects of the present disclosure and, together with the description, serve to explain principles of the present disclosure. In the drawings:

FIG. 1 is a block diagram of an electronic device according to an aspect of the present disclosure;

FIG. 2 is a schematic view of electronic devices according to aspects of the present disclosure;

FIG. 3 is a view illustrating a method for forming an organic emission layer by using an inkjet printing apparatus;

FIG. 4 is a view illustrating an example of a cross-section of any one pixel illustrated in FIG. 3;

FIG. 5A is a perspective view of an inkjet printing apparatus according to an aspect of the present disclosure;

FIG. 5B is a cross-sectional view illustrating a portion taken along line I-I′ in FIG. 5A;

FIG. 6 is a schematic perspective view illustrating a head unit according to an aspect of the present disclosure;

FIG. 7 is a plan view of an inkjet printing apparatus according to an aspect of the present disclosure;

FIGS. 8 to 10 are each a view illustrating a print area of a substrate according to an aspect of the present disclosure;

FIGS. 11A to 11D are schematic cross-sectional views illustrating a method for manufacturing a display panel according to an aspect of the present disclosure; and

FIGS. 11E and 11F are schematic perspective views illustrating a method for manufacturing a display panel according to an aspect of the present disclosure.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the present disclosure. Similarly, a second element, component, region, layer or section could be termed a first element, component, region, layer or section. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, aspects of the present disclosure are described with reference to the drawings.

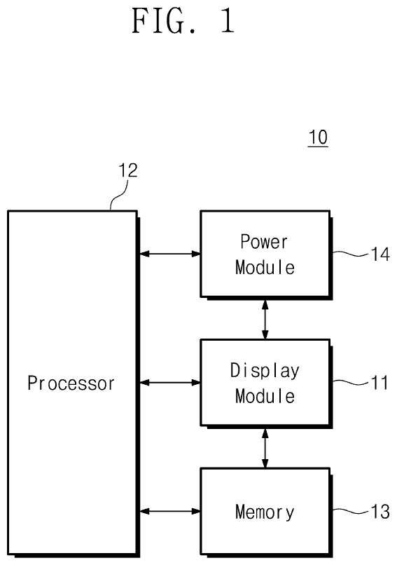

FIG. 1 is a block diagram of an electronic device according to an aspect of the present disclosure.

Referring to FIG. 1, an electronic device 10 according to an aspect may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module which converts the power supplied by the power supply module and generates power necessary for an operation of the electronic device 10.

At least one of the components of the electronic device 10 described above may be included in the display devices according to aspects described below. In addition, some of individual modules included as functional in one module may be included in the display device, and others may be provided separately from the display device. For example, the display device may include the display module 11, and the processor 12, the memory 13, and the power module 14 may be provided not in the display device but in another type of device in the electronic device 10.

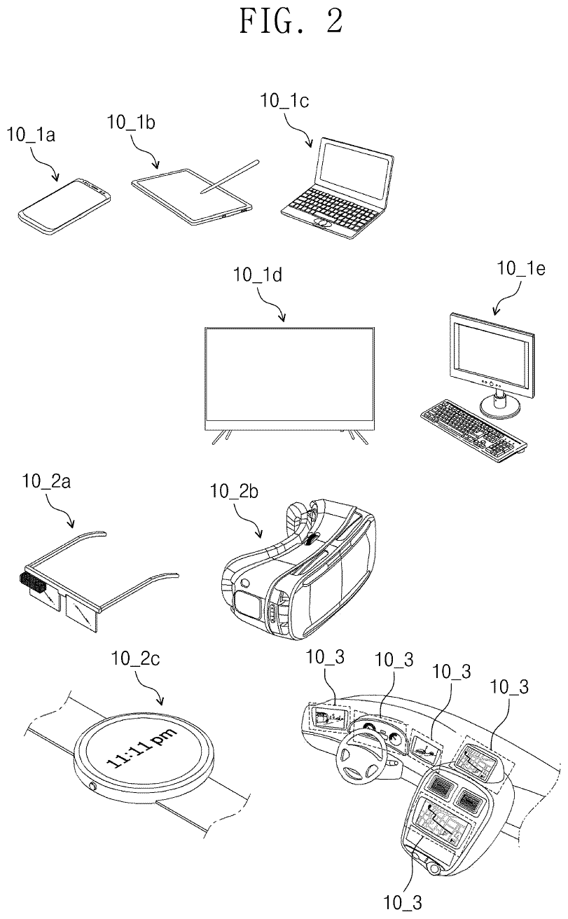

FIG. 2 is a schematic view of electronic devices according to aspects of the present disclosure.

Referring to FIG. 2, various electronic devices with applied display devices according to aspects may include not only an electronic device for image display, e.g., a smartphone 10_1a, a tablet PC 10_1b, a laptop computer 10_1c, TV 10_1d, and a monitor for a desk computer 10_1e, but also a wearable electronic device including a display module, e.g., smart glasses 10_2a, a head mounted display 10_2b, and a smart watch 10_2c, and a vehicle electronic device 10_3 including a display module, e.g., a vehicle instrument panel, a center fascia, a center information display (CID) disposed on a dashboard, and a room mirror display.

The electronic device may include the display device which displays an image, and a processor which processes an image signal and provides the image signal to the display device. The display device may include a display panel manufactured by a method for manufacturing a display panel which will be described later.

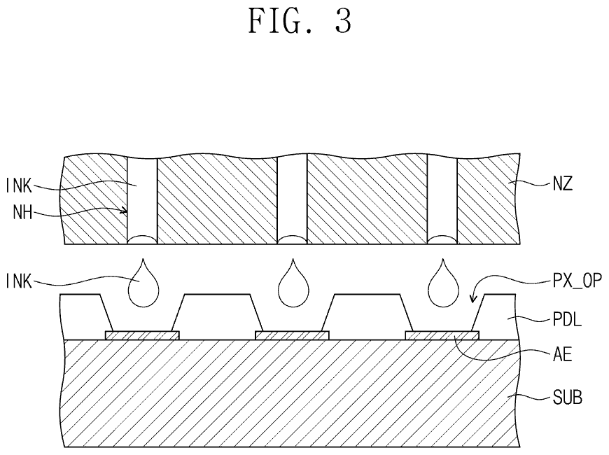

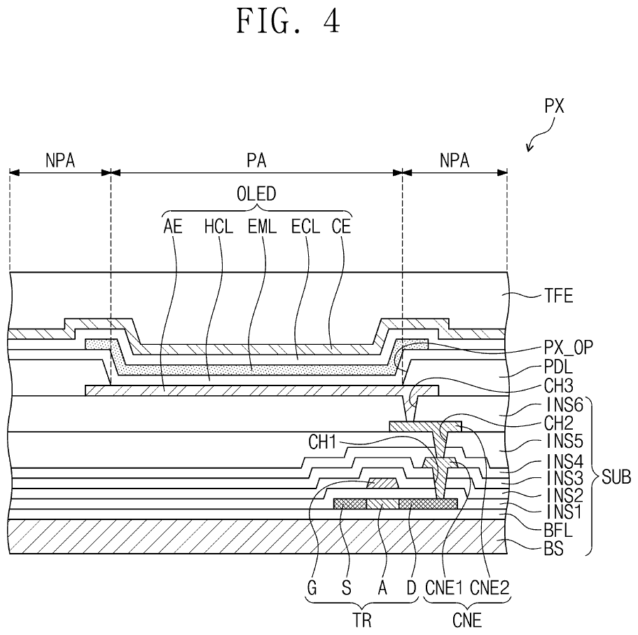

FIG. 3 is a view illustrating a method for forming an organic emission layer by using an inkjet printing apparatus. FIG. 4 is a view illustrating an example of a cross-section of any one pixel illustrated in FIG. 3.

For convenience of description, FIG. 3 illustrates an example of a cross-section of a portion of nozzles NZ in which three nozzle holes NH are defined.

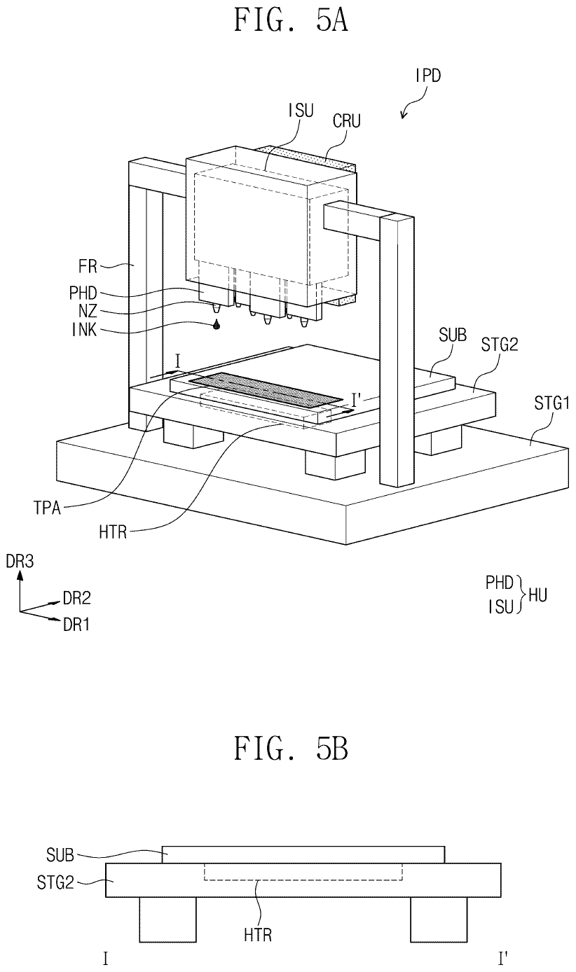

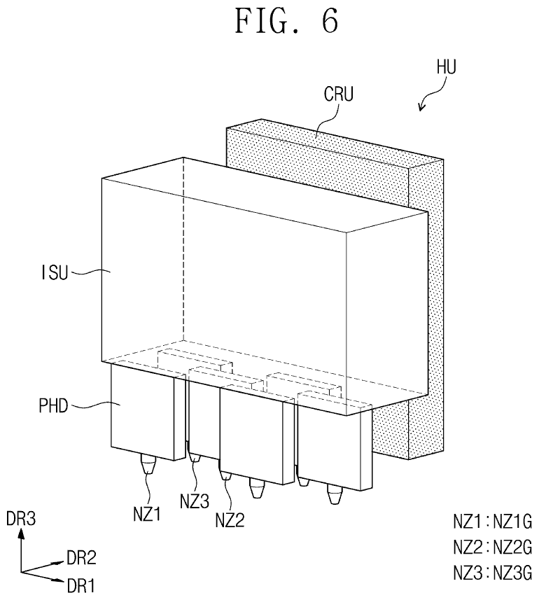

Referring to FIGS. 3 and 4, an inkjet printing apparatus IPD (see FIG. 5A) may be used to form an emission layer EML (see FIG. 4). A pixel PX may include a transistor TR and a light emitting element OLED connected to the transistor TR. Although one pixel PX is illustrated as an example, substantially a plurality of pixels PX may be disposed on a base layer BS.

The light emitting element OLED may include a first electrode AE, a second electrode CE, a hole control layer HCL, an electron control layer ECL, and the emission layer EML. The first electrode AE may be an anode electrode, and the second electrode CE may be a cathode electrode.

The transistor TR and the light emitting element OLED may be disposed on the base layer BS. A plane area of the base layer BS may be divided into an emission portion PA and a non-emission portion NPA around the emission portion PA. The light emitting element OLED may be disposed on the emission portion PA.

A buffer layer BFL may be disposed on the base layer BS, and the buffer layer BFL may be an inorganic layer.

Semiconductor patterns S, A and D may be disposed on the buffer layer BFL. The semiconductor patterns S, A and D may include polysilicon. However, the semiconductor patterns S, A and D are not limited thereto and may include amorphous silicon or a metal oxide.

The semiconductor patterns S, A and D may be doped with an n-type dopant or a p-type dopant. The semiconductor patterns may include a heavily doped region and a lightly doped region. The heavily doped region may have higher conductivity than the lightly doped region, and substantially serve as a source electrode and a drain electrode of the transistor TR. The lightly doped region may substantially correspond to an active (or channel) of the transistor.

A source S, an active A, and a drain D of the transistor TR may be provided from the semiconductor patterns S, A and D. A first insulating layer INS1 may be disposed on the semiconductor patterns S, A and D. A gate electrode G of the transistor TR may be disposed on the first insulating layer INS1. A second insulating layer INS2 may be disposed on the gate electrode G. A third insulating layer INS3 may be disposed on the second insulating layer INS2.

A connection electrode CNE may be disposed between the transistor TR and the light emitting element OLED and connect the transistor TR to the light emitting element OLED. The connection electrode CNE may include a first connection electrode CNE1 and a second connection electrode CNE2.

The first connection electrode CNE1 may be disposed on the third insulating layer INS3 and connected to the drain D through a first contact hole CH1 defined in the first to third insulating layers INS1 to INS3. A fourth insulating layer INS4 may be disposed on the first connection electrode CNE1. A fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 defined in the fifth insulating layer INS5. A sixth insulating layer INS6 may be disposed on the second connection electrode CNE2. The first to sixth insulating layers INS1 to INS6 may be an inorganic layer or an organic layer.

The first electrode AE may be disposed on the sixth insulating layer INS6. The first electrode AE may be connected to the second connection electrode CNE2 through a third contact hole CH3 defined in the sixth insulating layer INS6. A pixel defining film PDL which exposes a portion of the first electrode AE may be disposed on the first electrode AE and the sixth insulating layer INS6. An opening portion PX_OP for exposing the portion of the first electrode AE may be defined in the pixel defining film PDL.

The hole control layer HCL may be disposed on the first electrode AE and the pixel defining film PDL. The hole control layer HCL may be disposed, in common, in the emission portion PA and the non-emission portion NPA. The hole control layer HCL may include a hole transport layer and a hole injection layer.

The emission layer EML may be disposed on the hole control layer HCL. The emission layer EML may be disposed in an area corresponding to the opening portion PX_OP. The emission layer EML may include an organic material and/or an inorganic material. The emission layer EML may generate light of one of a red color, a green color, and a blue color.

The electron control layer ECL may be disposed on the emission layer EML and the hole control layer HCL. The electron control layer ECL may be disposed, in common, in the emission portion PA and the non-emission portion NPA. The electron control layer ECL may include an electron transport layer and an electron injection layer.

The second electrode CE may be disposed on the electron control layer ECL. The second electrode CE may be disposed, in common, in the pixels PX.

A thin film encapsulation layer TFE may be disposed on the light emitting element OLED. The thin film encapsulation layer TFE may be disposed on the second electrode CE and cover the pixel PX. The thin film encapsulation layer TFE may include at least two inorganic layers and an organic layer between the inorganic layers. The inorganic layers may protect the pixel PX from moisture/oxygen. The organic layer may protect the pixel PX from foreign matter such as dust particles.

A first voltage may be applied to the first electrode AE through the transistor TR, and a second voltage having a lower level than the first voltage may be applied to the second electrode CE. A hole and an electron which are injected into the emission layer EML may be bound to form an exciton, and as the exciton is transited into a ground state, the light emitting element OLED may emit light.

FIG. 5A is a perspective view of an inkjet printing apparatus according to an aspect of the present disclosure. FIG. 5B is a cross-sectional view illustrating a portion taken along line I-I′ in FIG. 5A.

Referring to FIGS. 5A and 5B, an inkjet printing apparatus IPD may include a first stage STG1, a second stage STG2, a substrate SUB, a head unit HU, a camera unit CRU, and a frame FR.

The second stage STG2 may be disposed on the first stage STG1. The second stage STG2 may include a heater HTR. An adsorption hole (not illustrated) may be defined in the second stage STG2. The substrate SUB may be adsorbed and fixed onto the second stage STG2 through the adsorption hole of the second stage STG2.

The substrate SUB may be disposed on the second stage STG2. The substrate SUB may include a print area TPA overlapping the heater HTR when viewed in plan view. The heater HTR may apply heat to the ink INK (see FIG. 3) to dry the ink INK. That is, the print area TPA may be coated with the ink INK, and the ink INK may be dried by the heater HTR.

The substrate SUB may move in a second direction DR2 on the second stage STG2. As the substrate SUB moves in the second direction DR2, the head unit HU may appear to move in the second direction DR2 relative to the second stage STG2 and relative to the substrate SUB.

The ink INK may include a material which emits excitation light in response to an electromagnetic wave. The ink INK may include a material which emits light with an intrinsic wavelength when being irradiated with light having a specific wavelength. For example, the ink INK may be a quantum dot material which emits light with an intrinsic wavelength when being irradiated with ultraviolet light.

The head unit HU may discharge the ink INK onto the substrate SUB. The ink INK discharged from the head unit HU may be cured on the substrate SUB to provide the emission layer EML (see FIG. 4). The head unit HU will be described later in detail.

The camera unit CRU may be disposed on a side surface of the head unit HU. The camera unit CRU may irradiate the ink INK with an electromagnetic wave and measure the excitation light generated in the ink INK. The frame FR may connect the first stage STG1 to the head unit HU.

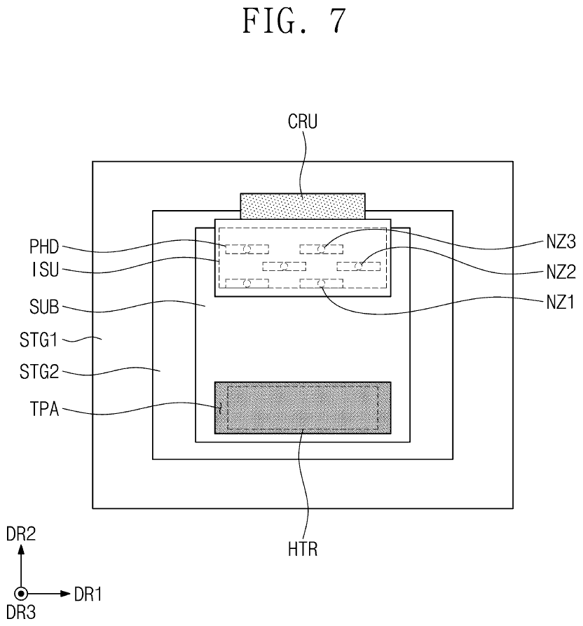

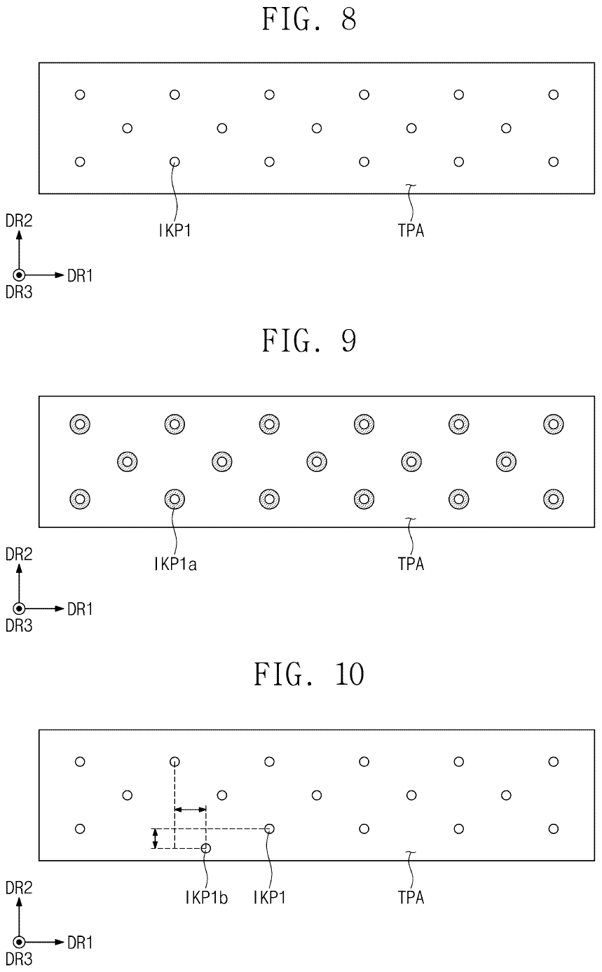

FIG. 6 is a schematic perspective view illustrating a head unit according to an aspect of the present disclosure. FIG. 7 is a plan view of an inkjet printing apparatus according to an aspect of the present disclosure.

For convenience of description, FIG. 6 illustrates an ink supply unit ISU, a plurality of printheads PHD, a plurality of nozzles NZ1, NZ2 and NZ3, and a camera unit CRU of a head unit HU. In FIG. 7, a frame FR and a heater HTR are omitted.

Referring to FIGS. 6 and 7, the head unit HU may be disposed above a substrate SUB and include the plurality of printheads PHD, the plurality of nozzles NZ1, NZ2 and NZ3, and the ink supply unit ISU.

The nozzles NZ1, NZ2 and NZ3 may be disposed on respective bottom surfaces of the printheads PHD. The nozzles may include a plurality of first nozzles NZ1 arranged in a first direction DR1. The plurality of first nozzles NZ1 may be defined as a first nozzle group NZ1G. The nozzles may include a plurality of second nozzles NZ2 arranged in the first direction DR1. The plurality of second nozzles NZ2 may be defined as a second nozzle group NZ2G. The nozzles may include a plurality of third nozzles NZ3 arranged in the first direction DR1. The plurality of third nozzles NZ3 may be defined as a third nozzle group NZ3G.

The first nozzle group NZ1G, the second nozzle group NZ2G, and the third nozzle group NZ3G may be arranged in a second direction DR2 crossing the first direction DR1. That is, the first nozzle group NZ1G, the second nozzle group NZ2G, and the third nozzle group NZ3G may be connected to the ink supply unit ISU and respectively grouped. As an example, FIGS. 6 and 7 illustrate the respective nozzles NZ1, NZ2 and NZ3 of the first nozzle group NZ1G, the second nozzle group NZ2G, and the third nozzle group NZ3G, but the number of the nozzles NZ1, NZ2 and NZ3 is not limited thereto as long as the nozzles NZ1, NZ2 and NZ3 are grouped.

The first nozzles NZ1 and the third nozzles NZ3 may be arranged in the same corresponding columns in the second direction DR2. The first nozzles NZ1 and the third nozzles NZ3 may overlap each other in the second direction DR2. The second nozzles NZ2 may be disposed in columns, each of which is between the columns in which the first nozzles NZ1 and the third nozzles NZ3 are disposed. That is, the second nozzles NZ2 may not overlap the first nozzles NZ1 and the third nozzles NZ3 in the second direction DR2. The second nozzles NZ2 may be disposed between the first nozzles NZ1 and the third nozzles NZ3 when viewed in the second direction DR2.

The ink supply unit ISU may be connected to the printheads PHD. The ink supply unit ISU may supply the ink INK (see FIG. 2) to the printheads PHD. The ink INK may be discharged from the nozzles NZ1, NZ2 and NZ3 through the ink supply unit ISU.

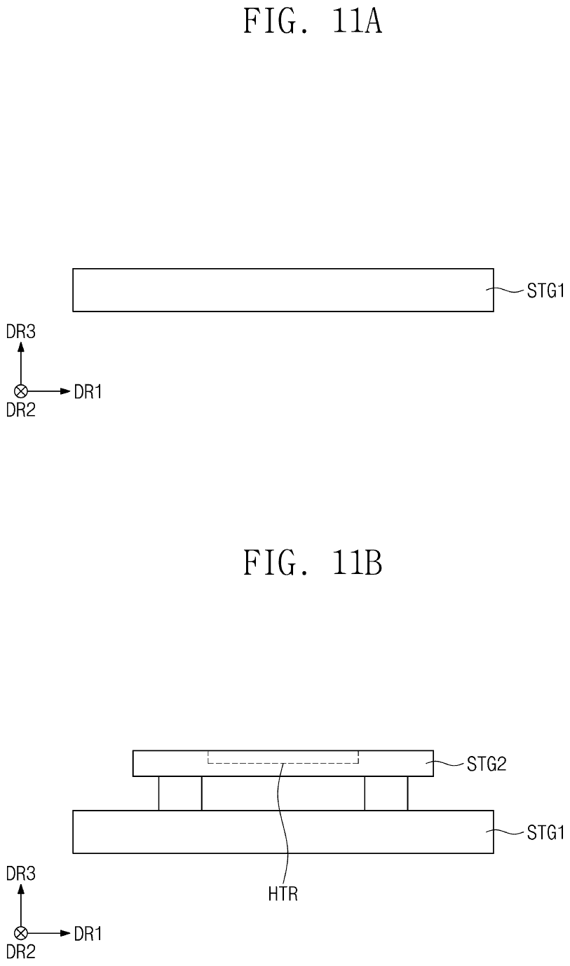

FIGS. 8 to 10 are each a view illustrating a print area of a substrate according to an aspect of the present disclosure.

Referring to FIGS. 5A and 8, an ink INK may be discharged from a plurality of first nozzles NZ1, a plurality of second nozzles NZ2, and a plurality of third nozzles NZ3. The ink INK discharged from the first nozzles NZ1, the second nozzles NZ2, and the third nozzles NZ3 may define a first ink pattern IKP1 in a print area TPA. That is, the ink INK may be provided to the print area TPA through the nozzles NZ of an inkjet printing apparatus IPD so that the first ink pattern IKP1 is defined. A plurality of first ink patterns IKP1 may be provided as illustrated in FIG. 8.

The first nozzles NZ1, the second nozzles NZ2, and the third nozzles NZ3 may be arranged to be equally spaced from each other in the first direction DR1. Respective distances between the first ink patterns IKP1 in the first direction DR1 may be the same. The ink INK may be simultaneously discharged from the first nozzles NZ1, the second nozzles NZ2, and the third nozzles NZ3 so that the first ink patterns IKP1 are arranged to be equally spaced from each other in the first direction DR1.

Referring to FIGS. 5A, 5B, and 9, after the ink INK is provided to the print area TPA, a heater HTR disposed below the print area TPA and inside a second stage STG2 may apply heat to the ink INK provided to the print area TPA. The heater HTR may apply the heat to the ink INK to evaporate a solvent of the ink INK, thereby defining a first ink pattern IKP1a.

The first ink pattern IKP1a may have a ring shape when viewed in plan view. As the solvent is evaporated, fluidity of the first ink pattern IKP1a as a liquid, which has a ring shape, may be decreased. Thus, a phenomenon in which the first ink pattern IKP1a moves in the print area TPA may be reduced or removed. In addition, noise generated as the result of an electromagnetic wave emitted from a camera unit CRU being reflected or scattered by the solvent of the ink INK may be reduced or removed.

When an electromagnetic irradiation unit of the camera unit CRU irradiates the first ink pattern IKP1a with an electromagnetic wave, excitation light of the first ink pattern IKP1a may not be generated in a central portion of the first ink pattern IKP1a by the electromagnetic wave because the first ink pattern IKP1a has a ring shape. Thus, a central position of the first ink pattern IKP1a may be accurately measured, and a hit position of the ink INK before drying may be accurately measured. In addition, a quantity of the emitted excitation light of the first ink pattern IKP1a may be measured to measure a volume of the ink INK discharged from the nozzles NZ before drying.

Referring to FIG. 10, a first ink pattern IKP1b is illustrated along with the first ink pattern IKP1. FIG. 10 differs from FIG. 8 in that one ink pattern, i.e. namely IKP1b, is in an error position. The error position is shifted in the first direction DR1 and in the second direction DR2. In an error of the first ink pattern IKP1b in the first direction DR1, printheads PHD may stop discharging the ink INK, and then the ink may be discharged from the printheads PHD except for a printhead having discharged the first ink pattern IKP1b, thereby correcting the position error.

In an error of the first ink pattern IKP1b in the second direction DR2, discharge timing of the ink INK from the nozzles NZ may be corrected to correct the error in the second direction DR2. That is, when a position error in the second direction DR2 occurs, the head unit HU, when forming the second ink pattern IKP2 discussed below, may be moved in the second direction DR2 and then discharge the ink INK, thereby correcting the position error in the second direction DR2.

In addition, each of the printheads PHD may further include a pressure element (not illustrated). When the volume of the discharged ink INK is large, the quantity of the excitation light emitted by the ink INK in response to the electromagnetic wave may be large. On the other hand, when the volume of the discharged ink INK is small, the quantity of the excitation light emitted by the ink INK in response to the electromagnetic wave may be small. Thus, the volume of the discharged ink INK may be measured using the quantity of the excitation light measured by the camera unit CRU. When a volume error in the discharged ink INK occurs, a discharge drive waveform for the pressure element may be adjusted to adjust a discharge a corrected amount of the ink INK in forming the second ink pattern IKP2 discussed below.

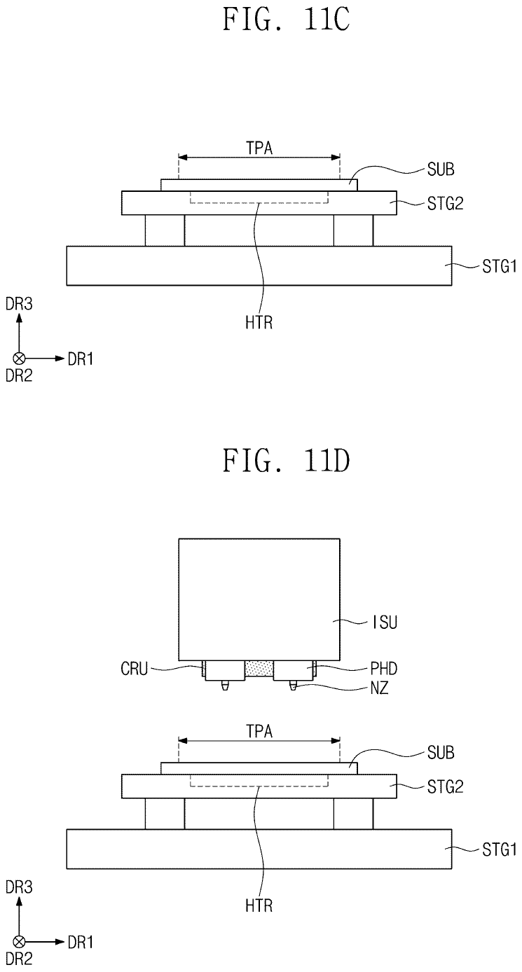

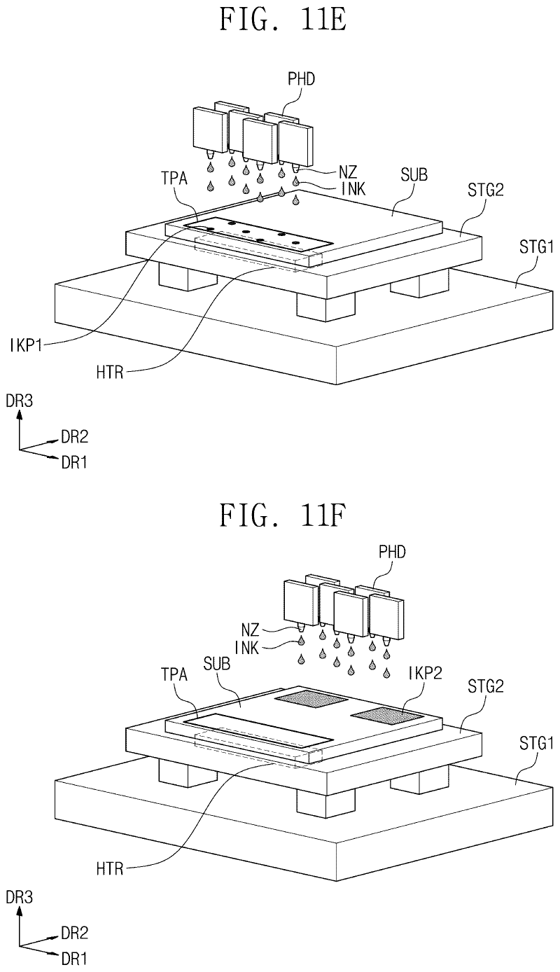

FIGS. 11A to 11D are schematic cross-sectional views illustrating a method for manufacturing a display panel according to an aspect of the present disclosure. FIGS. 11E and 11F are schematic perspective views illustrating a method for manufacturing a display panel according to an aspect of the present disclosure.

In FIGS. 11E and 11F, components except for a plurality of printheads PHD and a plurality of nozzles NZ are omitted in a head unit HU for convenience of description.

Referring to FIG. 11A, the method for manufacturing the display panel may include preparing a first stage STG1.

Referring to FIG. 11B, the method for manufacturing the display panel may include arranging a second stage STG2 on the first stage STG1. A heater HTR may be disposed inside the second stage STG2.

Referring to FIG. 11C, the method for manufacturing the display panel may include arranging a substrate SUB on the second stage STG2. The substrate SUB may include a print area TPA overlapping the heater HTR when viewed in plan view.

Referring to FIGS. 5A and 11D, the method for manufacturing the display panel may include arranging a head unit above the substrate SUB. The method for manufacturing the display panel may include arranging, on a side surface of the head unit HU, a camera unit CRU which irradiates an ink INK with an electromagnetic wave and measures excitation light generated in the ink INK.

The head unit HU may include the plurality of printheads PHD, an ink supply unit ISU which supplies, to the printheads PHD, the ink INK including a material which emits the excitation light in response to the electromagnetic wave, and the plurality of nozzles NZ disposed on respective bottom surfaces of the printheads PHD.

Referring to FIGS. 5A, 5B, and 11E, the method for manufacturing the display panel may include allowing the nozzles NZ to discharge the ink INK to a print area TPA to form a first ink pattern IKP1. The method for manufacturing the display panel may include measuring excitation light of the first ink pattern IKP1 by the camera unit CRU.

The camera unit CRU may further include an electromagnetic irradiation unit (not illustrated) which emits the electromagnetic wave. The ink INK may be discharged to the print area TPA through the nozzles INK, and then the ink INK may be provided to the print area TPA so that the first ink pattern IKP1 is formed.

The measuring of the excitation light of the first ink pattern IKP1 by the camera unit CRU may include irradiating the first ink pattern IKP1 with the electromagnetic wave by the electromagnetic irradiation unit to measure a central position and a quantity of the excitation light. When the first ink pattern IKP1 emits excitation light in response to the electromagnetic wave, the camera unit CRU may measure the excitation light. Whether the first ink patterns IKP1 discharged are equally spaced from each other and whether a target volume of the ink INK was discharged may be determined by measuring the excitation light.

The method for manufacturing the display panel may further include adjusting the amount of time the ink supply unit ISU supplies the ink INK, after the measuring of the excitation light of the first ink pattern IKP1 by the camera unit CRU. When the target volume of the ink INK is not discharged, the ink supply unit ISU may adjust the amount of time the ink INK is supplied so that the target volume of the ink INK is discharged.

Each of the printheads PHD may further include a pressure element (not illustrated). The method for manufacturing the display panel may further include adjusting a discharge amount of the ink INK discharged from the nozzles NZ by the pressure element, after the measuring of the excitation light of the first ink pattern IKP1 by the camera unit CRU. After the excitation light of the first ink pattern IKP1 is measured, a discharge drive waveform for the pressure elements of the printheads PHD may be adjusted to adjust the discharge amount of the ink INK when the target volume of the ink INK is not discharged. As a result, the target volume of the ink INK may be discharged from the nozzles NZ.

The method for manufacturing the display panel may further include drying the first ink pattern IKP1 by the heater HTR, and then after drying, measuring of the excitation light of the first ink pattern IKP1a. discussed below, by the camera unit CRU.

The first ink pattern IKP1 may be dried to form the first ink pattern IKP1a (see FIG. 9) in which a solvent of the ink INK is evaporated. A volume or position error of the ink INK generated as the result of the ink INK being reflected or scattered when emitting the excitation light may be reduced or removed through the dried first ink pattern IKP1a.

Referring to FIGS. 5A and 11F, the method for manufacturing the display panel may include forming, on the substrate SUB, a second ink pattern IKP2 spaced from the print area TPA by using the nozzles NZ. An inkjet printing apparatus IPD may further include the second ink pattern IKP2 disposed on the substrate SUB and spaced from the print area TPA. The method for manufacturing the display panel may include curing the second ink pattern IKP2 to form the emission layer EML (see FIG. 4). The first ink pattern IKP1 (see FIG. 11E) may be formed to correct the discharge amount of the ink INK and a hit position of the ink, and then the head unit HU may move in the second direction. That is, the nozzles NZ may move in the second direction DR2 to discharge the ink INK onto the substrate SUB spaced apart from the print area TPA. The ink INK may be discharged onto the substrate SUB to form the second ink pattern IKP2. The second ink pattern IKP2 may be cured on the substrate SUB to form the emission layer EML.

As described above, the first ink pattern may have the ring shape when viewed in plan view. As the solvent is evaporated, the fluidity of the first ink pattern as a liquid, which has the ring shape, may be decreased. Thus, the phenomenon in which the first ink pattern moves in the print area may be reduced or removed. In addition, the noise generated as the result of the electromagnetic wave emitted from the camera unit being reflected or scattered by the solvent of the ink may be reduced or removed.

As the first ink pattern has the ring shape, the excitation light of the first ink pattern may not be generated in the central portion of the first ink pattern by the electromagnetic wave. Thus, the central portion of the first ink pattern may be accurately measured, and the hit position of the ink before the drying may be accurately measured. In addition, the quantity of the emitted excitation light of the first ink pattern may be measured to measure the volume of the ink discharged from the nozzles before the drying.

In the above, description has been made with reference to aspects of the present disclosure, but those skilled or of ordinary skill in the art may understand that various modifications and changes may be made to the present disclosure insofar as such modifications and changes do not depart from the spirit and technical scope of the present disclosure.

Therefore, the technical scope of the present disclosure is not to be limited to the contents stated in the detailed description of the specification.

What is claimed is:

1. An inkjet printing apparatus comprising:
a first stage;
a second stage disposed on the first stage, the second stage comprising a heater, a substrate disposed on the second stage, the substrate comprising a print area, the print area overlapping the heater;
a head unit disposed above the substrate, and comprising a plurality of printheads and an ink supply unit configured to supply the printheads with an ink comprising a material which emits excitation light in response to an electromagnetic wave; and
a camera unit disposed on a side surface of the head unit and configured to irradiate the ink with the electromagnetic wave and measure the excitation light generated by the ink.

2. The inkjet printing apparatus of claim 1, wherein the head unit further comprises a plurality of nozzles, each of the plurality of nozzles is disposed on a bottom surface of one of the plurality of printheads.

3. The inkjet printing apparatus of claim 2, wherein the nozzles comprise:
a plurality of first nozzles defined as a first nozzle group and arranged in a first direction;
a plurality of second nozzles defined as a second nozzle group and arranged in the first direction; and
a plurality of third nozzles defined as a third nozzle group and arranged in the first direction,
wherein the first nozzle group, the second nozzle group, and the third nozzle group are arranged in a second direction crossing the first direction.

4. The inkjet printing apparatus of claim 3, wherein the first nozzles and the third nozzles are arranged in the same corresponding columns in the second direction, and
the second nozzles are disposed in columns, each of which is between the columns in which the first nozzles are disposed.

5. The inkjet printing apparatus of claim 2, wherein the nozzles are configured to provide the ink to the print area of the substrate so that a first ink pattern is defined.

6. The inkjet printing apparatus of claim 5, wherein the heater is configured to dry the first ink pattern to form a ring shape ink pattern when viewed in plan view.

7. The inkjet printing apparatus of claim 2, wherein the nozzles are configured to provide the ink to an area on the substrate, spaced apart from the print area of the substrate, so that a second ink pattern is defined.

8. The inkjet printing apparatus of claim 1, wherein an adsorption hole is defined in the second stage.

9. The inkjet printing apparatus of claim 1, wherein the camera unit further comprises an electromagnetic irradiation unit.

10. The inkjet printing apparatus of claim 1, wherein each of the printheads further comprises a pressure element.

11. The inkjet printing apparatus of claim 1, further comprising a frame connecting the first stage to the head unit.

12. A method for manufacturing a display panel, the method comprising:
providing a first stage;
disposing a second stage on the first stage, the second stage comprising a heater;
arranging, on the second stage, a substrate comprising a print area so that the print area overlaps the heater;
arranging, above the substrate, a head unit comprising a plurality of printheads, an ink supply unit configured to supply the printheads with an ink comprising a material that emits excitation light in response to an electromagnetic wave, and a plurality of nozzles, each disposed on a respective bottom surface of one of the printheads;
arranging, on a side surface of the head unit, a camera unit;
discharging the ink to the print area of the substrate through the nozzles to form a first ink pattern;
using the camera unit to irradiate the first ink pattern with an electromagnetic wave;
using the camera unit to measure an excitation light of the first ink pattern;
discharging the ink to an area on the substrate spaced apart from the print area of the substrate to form a second ink pattern; and
curing the second ink pattern to form an emission layer of the display panel.

13. The method of claim 12, wherein the camera unit further comprises an electromagnetic irradiation unit,
wherein using the camera unit to measure the excitation light of the first ink pattern comprises using electromagnetic irradiation unit to irradiate the first ink pattern with the electromagnetic wave, and
wherein using the camera unit to measure comprises measuring a central position and a quantity of the excitation light.

14. The method of claim 12, further comprising, after using the camera to measure, adjusting an amount of time the ink supply unit supplies the ink to the printheads.

15. The method of claim 12, wherein each of the printheads further comprises a pressure element, and
the method further comprising, after using the camera unit to measure, using the pressure element to adjust an amount of the ink discharged from the nozzles.

16. The method of claim 12, further comprising, before using the camera unit to measure and before using the camera unit to irradiate, using the heater to dry the first ink pattern.

17. An electronic device comprising:
a display device configured to display an image; and
a processor configured to process an image signal and provide the image signal the display device,
wherein the display device comprises a display panel manufactured by:
providing a first stage;
disposing a second stage on the first stage, the second stage comprising a heater;
arranging, on the second stage, a substrate comprising a print area so that the print area overlaps the heater;
arranging, above the substrate, a head unit comprising a plurality of printheads, an ink supply unit configured to supply the printheads an ink comprising a material that emits excitation light in response to an electromagnetic wave, and a plurality of nozzles, each disposed on a respective bottom surface of one of the printheads;
arranging, on a side surface of the head unit, a camera unit;
discharging the ink to the print area of the substrate through the nozzles to form a first ink pattern;
using the camera unit to irradiate the first ink pattern with an electromagnetic wave;
using the camera unit to measure an excitation light of the first ink pattern;
discharging the ink to an area on the substrate spaced apart from the print area of the substrate to form a second ink pattern; and
curing the second ink pattern to form an emission layer of the display panel.
